(19) United States
(12) Patent Application Publication
(10) Pub. No.: US 2021/0152770 A1
(43) Pub. Date: May 20, 2021

(54) SYSTEMS AND METHODS FOR GENERATING TIME TRACE INFORMATION

(71) Applicant: SEMICONDUCTOR COMPONENTS INDUSTRIES, LLC, Phoenix, AZ (US)

(72) Inventors: Manuel H. INNOCENT, Wezemaal (BE); Christopher PARKS, Pittsford, NY (US); John P. MCCARTEN, Penfield, NY (US)

(73) Assignee: SEMICONDUCTOR COMPONENTS INDUSTRIES, LLC, Phoenix, AZ (US)

(21) Appl. No.: 16/686,395

(22) Filed: Nov. 18, 2019

(51) Int. Cl. H04N 5/372; H01L 27/148; H04N 5/378

(52) U.S. Cl. CPC H04N 5/37206; H01L 27/14806; G01S 7/4863; H04N 5/378; H01L 27/14843

(57) ABSTRACT

An imaging system may include an array of image sensor pixels, each image sensor pixel including a photosensitive element coupled to time trace generation circuitry having a first CCD register. The time trace generation circuitry may be coupled to integration circuitry having a second integration CCD register via corresponding charge transfer structures. The second integration CCD register may integrate multiples sets of sampled charge from the first CCD register to improve the signal-to-noise ratio of the collected time trace information. The time trace generations circuitry or integration circuitry may also include background light subtract capabilities to remove background light level from the collected time trace information.

### BACKGROUND

This relates generally to imaging devices, and more particularly, to imaging devices for generating time trace information and/or gathering time of flight measurements.

Image sensors are commonly used in devices and systems such as cellular telephones, cameras, computers, and automotive systems to capture images and generate time trace information. In a typical arrangement, an image sensor measures light intensity over a time period to identify light reflected from an object and time of flight information for the reflected light. This can be used to enable light detection and ranging (LiDAR) applications.

In some implementations, single-photon avalanche diodes (SPADs) are used to generate the time trace information. However, obtaining the time trace information from individual photon arrival times requires large amounts of high speed digital processing, which is undesirable in some applications. While charge-coupled devices (CCDs) can be used for capturing a time trace of the incoming (reflected) light signal, challenges may arise when trying to achieve a satisfactory signal to noise ratio for the captured incoming light signal and to achieve other performance criteria.

It would therefore be desirable to be able to provide imaging systems with improved time of flight measurement capabilities and time trace information generation capabilities.

### BRIEF DESCRIPTION OF THE DRAWINGS

FIG. 1 is a diagram of an illustrative imaging system or device having an image sensor and processing circuitry in accordance with some embodiments.

FIG. 2 is a diagram of an illustrative image sensor having a pixel array and associated readout and control circuitry in accordance with some embodiments.

FIG. 3 is a diagram of an illustrative image pixel configured to generate integrated time trace information in accordance with some embodiments.

FIG. 4 is a diagram of illustrative time trace generation circuitry and integration circuitry in accordance with some embodiments.

FIG. 5 is a diagram of illustrative time trace generation circuitry and integration circuitry having portions operable at different speeds in accordance with some embodiments.

FIG. 6 is a diagram of illustrative time trace integration circuitry having background light subtraction capabilities in accordance with some embodiments.

FIG. 7 is a diagram of illustrative time trace generation circuitry having background light subtraction capabilities in accordance with some embodiments.

FIG. 8 is a diagram of an illustrative configuration for coupling an array of photosensitive elements to integrated time trace generation circuitry in accordance with some embodiments.

FIG. 9 is a diagram of illustrative time trace generation circuitry configured in a loop in accordance with some embodiments.

FIG. 10 is a diagram of illustrative control driver circuitry and pixel circuitry implemented on separate stacked dies in accordance with some embodiments.

FIG. 11 is a diagram of an illustrative configuration for coupling an array of photosensitive elements to integrated time trace generation circuitry and background light integration circuitry in accordance with some embodiments.

### DETAILED DESCRIPTION

Electronic devices such as digital cameras, computers, cellular telephones, and other electronic devices may include image sensors that gather incoming light to capture an image. The image sensors may include arrays of image pixels. The pixels in the image sensors may include photosensitive elements such as photodiodes that convert the incoming light into sets of electric charge (e.g., corresponding to image signals). Image sensors may have any number of pixels (e.g., hundreds or thousands or more). A typical image sensor may, for example, have hundreds of thousands or millions of pixels (e.g., megapixels). If desired, an image sensor may have fewer than hundreds of thousands of pixels in some configurations. Image sensors may include control circuitry such as circuitry for operating the image pixels and readout circuitry for reading out image signals corresponding to the electric charge generated by the photosensitive elements.

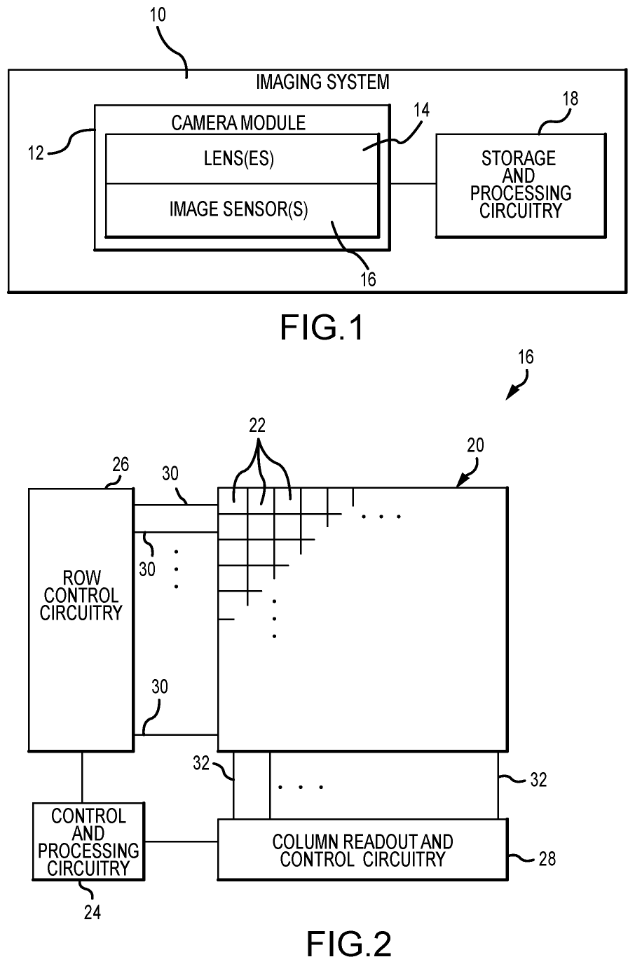

FIG. 1 is a diagram of an illustrative imaging system such as an electronic device that uses an image sensor to capture images. Electronic device 10 of FIG. 1 may be a portable electronic device such as a camera, a cellular telephone, a tablet computer, a webcam, a video camera, a video surveillance system, an automotive imaging system, a video gaming system with imaging capabilities, or any other desired imaging system or device that captures image data. Camera module 12 (sometimes referred to as an imaging module) may be used to convert incoming light into (digital) image data. Camera module 12 may include one or more lenses 14 and one or more corresponding image sensors 16. Lenses 14 may include fixed and/or adjustable lenses and may include microlenses formed on an imaging surface of image sensor 16 and other macro lenses. During image capture operations, light from a scene may be focused onto image sensor 16 by lenses 14. Image sensor 16 may include circuitry for converting analog pixel image signals into corresponding digital image data to be provided to storage and processing circuitry 18. If desired, camera module 12 may be provided with an array of lenses 14 and an array of corresponding image sensors 16.

Storage and processing circuitry 18 may include one or more integrated circuits (e.g., image processing circuits, microprocessors, storage devices such as random-access memory and non-volatile memory, etc.) and may be implemented using components that are separate from the camera module and/or that form part of the camera module (e.g., circuits that form part of an integrated circuit that includes image sensors 16 or an integrated circuit within the module that is associated with image sensors 16). When storage and processing circuitry 18 is included on different integrated circuits (e.g., chips) than those of image sensors 16, the integrated circuits with circuitry 18 may be vertically stacked or packaged with respect to the integrated circuits with image sensors 16. Image data that has been captured by camera module 12 may be processed and stored using processing circuitry 18 (e.g., using an image processing engine on processing circuitry 18, using an imaging mode selection engine on processing circuitry 18, etc.). Processed image data may, if desired, be provided to external equipment (e.g., a computer, external display, or other device) using wired and/or wireless communications paths coupled to processing circuitry 18.

As shown in FIG. 2, image sensor 16 may include a pixel array 20 containing image sensor pixels 22 arranged in rows and columns (sometimes referred to herein as image pixels or pixels) and control and processing circuitry 24. Array 20 may contain, for example, hundreds or thousands of rows and columns of image sensor pixels 22. Because each image sensor pixel may include at least one photosensitive element, array 20 may be referred to herein sometimes as an array of photosensitive elements. Control circuitry 24 may be coupled to row control circuitry 26 and image readout circuitry 28 (sometimes referred to as column control circuitry, column readout circuitry, readout circuitry, or column decoder circuitry). Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22. If desired, during pixel readout operations, a pixel row in array 20 may be selected using row control circuitry 26 and image signals generated by image pixels 22 in that pixel row may be read out along column lines 32.

Readout circuitry 28 may receive image signals (e.g., analog pixel values generated by pixels 22) over column lines 32. Readout circuitry 28 may include sample-and-hold circuitry for sampling and temporarily storing image signals read out from array 20, amplifier circuitry or a multiplier circuit, analog-to-digital conversion (ADC) circuitry, bias circuitry, column memory, latch circuitry for selectively enabling or disabling the column circuitry, or other circuitry that is coupled to one or more columns of pixels in array 20 for operating pixels 22 and/or for reading out image signals from pixels 22. ADC circuitry in readout circuitry 28 may convert analog pixel values received from array 20 into corresponding digital pixel values (sometimes referred to as digital image data or digital pixel data). Readout circuitry 28 may supply digital pixel data to control and processing circuitry 24 and/or processor 18 (FIG. 1) for pixels in one or more pixel columns.

If desired, image pixels 22 may include more than one photosensitive elements for generating charge in response to image light. One or more photosensitive elements within image pixels 22 may be arranged in rows and columns on array 20. Pixel array 20 may be provided with a filter array having multiple (color) filter elements (each corresponding to a respective pixel) which allows a single image sensor to sample light of different colors or sets of wavelengths. As an example, image sensor pixels such as the image pixels in array 20 may be provided with a color filter array having red, green, and blue filter elements, which allows a single image sensor to sample red, green, and blue (RGB) light using corresponding red, green, and blue image sensor pixels arranged in a Bayer mosaic pattern.

In another suitable example, the green pixels in a Bayer pattern may be replaced by broadband image pixels having broadband color filter elements (e.g., clear color filter elements, yellow color filter elements, etc.). In yet another example, one of the green pixels in a Bayer pattern may be replaced by infrared (IR) image pixels formed under IR color filter elements and/or the remaining red, green, and blue image pixels may also be sensitive to IR light (e.g., may be formed under filter elements that pass IR light in addition to light of their respective colors). These examples are merely illustrative and, in general, filter elements of any desired color and/or wavelength and in any desired pattern may be formed over any desired number of image pixels 22. If desired, one or more filter elements over array 20 may be omitted.

Separate microlenses may be formed over each image pixel 22 (e.g., with light or color filter elements interposed between the microlenses and image pixels 22). The microlenses may form an array of microlenses that overlap the array of light filter elements and array 20. Each microlens may focus light from an imaging system lens onto a corresponding image pixel 22, or multiple image pixels 22 if desired.

Image pixels 22 may be formed in a semiconductor substrate using complementary metal-oxide-semiconductor (CMOS) technology, charge-coupled device (CCD) technology, both CMOS and CCD technologies, or any other suitable photosensitive device technology. Image pixels 22 may be frontside illumination (FSI) image pixels or backside illumination (BSI) image pixels. If desired, image sensor 16 may include an integrated circuit package or other structure in which multiple integrated circuit substrate layers or chips are vertically stacked with respect to each other. In this scenario, one or more of circuitry 24, 26, and 28 may be vertically stacked above or below array 20 within image sensor 16. If desired, lines 32 and 30 may be formed from vertical conductive via structures (e.g., through-silicon vias, through-oxide vias, etc.) and/or horizontal interconnect lines.

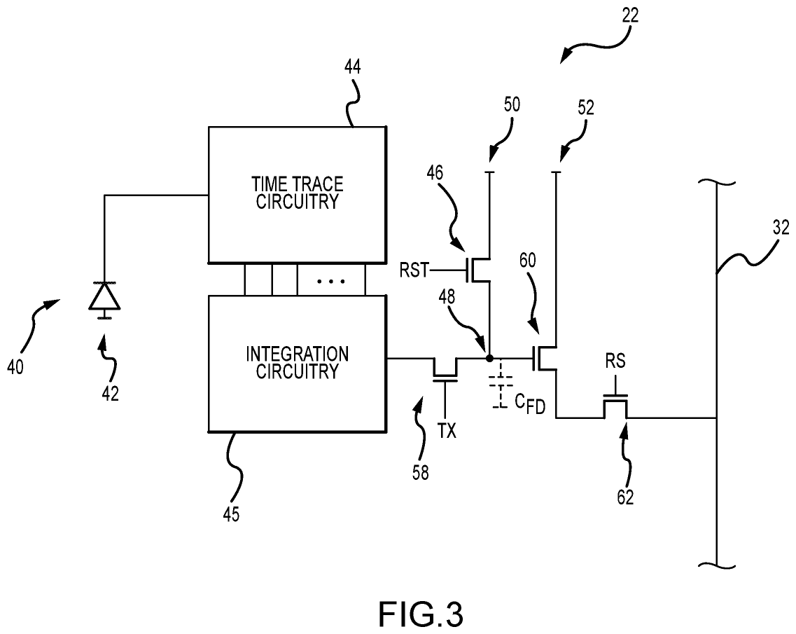

FIG. 3 is a diagram of an illustrative image pixel 22. As shown in FIG. 3, pixel 22 may include a photosensitive element such as photodiode 40. A first terminal photodiode 40 may be coupled to supply terminal 42. As an example, terminal 42 may be a voltage source supplying a ground voltage. Incoming light may be received by photodiode 40. Photodiode 40 may generate charge (e.g., electrons) in response to receiving impinging photons. The amount of charge that is collected by photodiode 40 depends on the intensity of the impinging light and the exposure duration (or integration time).

To enable generation of time trace information, a second terminal of photodiode 40 may be coupled to time trace circuitry 44 (sometimes referred to herein as time trace generation circuitry or register circuitry). Time trace generation circuitry 44 may be implemented using charge-coupled device (CCD) structures. As such, circuitry 44 may be referred to herein as CCD time trace generation circuitry or simply CCD circuitry. In particular, the CCD structures may include a plurality of series-connected charge storage structures (e.g., serially-connected two-terminal MOS capacitors, charge storage well structures, etc.) each of which is configured to store charge. Control circuitry may control the charge storage structures to transfer each of the stored charge along the serial path of the series-connected charge storage structures in time trace circuitry 44.

In other words, time trace generation circuitry 44 may serve as a shift register for the charge generated at photodiode 40. By shifting the charge generated at photodiode 40, the spatial resolution provided by the different amounts of charge stored at each well in time trace generation circuitry 44 may be correlated to temporal information of when each of the different amounts of charge was generated by photodiode 40 (e.g., when incoming light corresponding to each of the different amounts of charge was received by photodiode 40). This may allow downstream processing circuitry (e.g., processing circuitry 18 in FIG. 1) to generated a time trace.

To enhance the time trace information generated by time trace circuitry 44, time trace circuitry 44 may be coupled to integration circuitry 45 (sometimes referred to herein as charge integration circuitry, time trace integration circuitry, or charge accumulation circuitry). If desired, charge transfer transistors or other charge transfer structures may be interposed along the paths between time trace circuitry 44 and integration circuitry 45.

Integration circuitry 45 may be implemented using charge-coupled device (CCD) structures. As such, circuitry 45 may be referred to herein as CCD integration circuitry or simply CCD circuitry. The CCD structure may include a plurality of series-connected charge storage structures (e.g., serially-connected two-terminal MOS capacitors, charge storage well structures, etc.) each of which is configured to store charge. Control circuitry may control the charge storage structures to transfer each of the stored charge along the serial path of the series-connected charge storage structures in integration circuitry 45. In a configuration described herein as an example, each of the charge storage structures in integration circuitry 45 may have a charge storage capacity (e.g., well capacity) that is greater than each of the charge storage structures in time trace circuitry 44. As example, a charge storage structure in integration circuitry 45 may have a charge storage capacity that is greater than two times, greater than three times, greater than five times, greater than ten times, or greater than any other suitable times the charge storage capacity of a charge storage structure in time trace circuitry 44.

By coupling time trace circuitry 44 to integration circuitry 45, multiple sets of charges corresponding to different time traces generated by time trace circuitry 44 may be integrated at integration circuitry 45. This may help enhance the signal detected by photodiode 40 (e.g., the integrated time trace may provide an improved signal-to-noise ratio). Additionally, integration circuitry 45 may perform the integration operation in the analog domain.

As an example, photodiode 40 may detect a signal emitted by a light source (e.g., a laser) and reflected from an object. The reflected signal detected and received by photodiode 40 may be used to generate a time trace to measure a time of flight for the emitted (reflected) signal. To keep the light source power within practical (regulatory) limits, multiple pulses may be sent using the light source. Consequently, instead of basing the time of flight measurement off of the single signal emitted by the light source, the light source may emit multiple sets of signals, each of which may be detected and received by photodiode 40 and each of which may be used to generated a corresponding time trace. The multiple sets of time traces may be accumulated (e.g., integrated or summed) at integration circuitry 45 to generated an integrated time trace having an improved signal-to-noise ratio.

The light pulses (e.g., emitted signals from the light source) may be provided at regular intervals or may be provided at pseudo-random times (which reduces the effects of systematic interference from other systems). Operation of time trace circuitry 44 may be synchronized to when the light pulses are generated or provided.

To effectively integrate charge from multiple time traces, time trace circuitry 44 may be coupled to integration circuitry 45 at multiple locations (e.g., multiple charge storage structures in time trace circuitry 44 may be respectively coupled to corresponding charge storage structures in integration circuitry 45). These locations may be the locations at which portions of the time traces (e.g., corresponding charge in the time traces) are integrated.

The configuration of time trace circuitry 44 and integration circuitry 45 within pixel 22 in FIG. 3 is merely illustrative. If desired, time trace circuitry 44 and integration circuitry 45 may be implemented and configured in any suitable manner. If desired, time trace circuitry 44 and/or integration circuitry 45 may be shared between different pixels 22 in array 20.

In the example of FIG. 3, pixel 22 may include charge storage region 48 (sometimes referred to herein as a floating diffusion region). Floating diffusion region 48 may have a capacitance C_{FD}. As an example, floating diffusion region 48 may be a doped semiconductor region (e.g., a region in a silicon substrate that is doped by ion implantation, impurity diffusion, or other doping process). Charge transfer transistor 58, controlled by control signal TX, may couple integration circuitry 45 to floating diffusion region 48. Floating diffusion region 48 may sequentially receive charge stored at each of the charge storage regions in integration circuitry 45 through charge transfer transistor 58.

Reset transistor 46 controlled by control signal RST may couple supply terminal 50 to floating diffusion region 48. As an example, supply terminal 50 may be a voltage source supplying a positive power supply voltage. Transistor 46 may be turned on to reset floating diffusion region 47 to a reset voltage (e.g., the voltage at supply terminal 50).

The voltage levels stored at floating diffusion region 48 (e.g., the charge received from integration circuitry 45) may be read out using charge readout circuitry. The charge readout circuitry may include source follower transistor 60 and row select transistor 62. The signal stored at charge storage region 48 may include a reset (or background) level signal and/or an image level signal. Transistor 60 may couple supply terminal 52 to transistor 62. As an example, supply terminal 52 may be a voltage source supplying a positive power supply voltage (e.g., the same positive power supply voltage supplied by supply terminal 50). Row select transistor 62 may have a gate terminal that is controlled by a row select signal (e.g., control signal RS). When the row select signal is asserted, transistor 62 is turned on and a pixel output signal (e.g. an output signal having a magnitude that is proportional to the amount of charge at floating diffusion region 48) is passed onto a pixel output path (e.g., column line 32 in FIGS. 2 and 3).

The configuration of pixel 22 in FIG. 3 is merely illustrative. If desired, other circuitry may be included in addition to or instead of the circuitry shown in FIG. 3. As an example, pixel 22 may include a photodiode reset transistor or anti-blooming transistor. As another example, pixel 22 may include an additional charge transfer transistor coupling photodiode 40 to time trace circuitry 44. If desired, one or more portions of pixel 22 in FIG. 3 may be omitted. As examples, amplifier circuitry in pixel 22 (e.g., transistor 60 and/or floating diffusion region 48 and associated circuitry) may be omitted, integration circuitry 45 may be coupled to pixel output path 32 without these interposing circuitry, and amplifier circuitry may be implemented downstream from pixel 22 (e.g., in column readout circuitry 28).

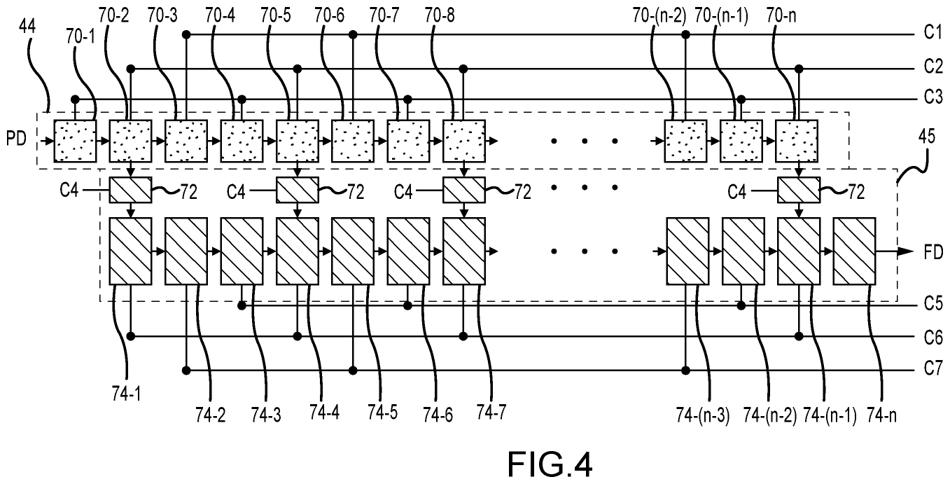

FIG. 4 is a diagram of illustrative time trace generation circuitry and illustrative integration circuitry. Described herein as an illustrative example, time trace generation circuitry 44 and integration circuitry 45 in FIG. 4 may be implemented in one or more pixels 22 in FIGS. 2 and 3.

As shown in FIG. 4, time trace generation circuitry 44 may include CCD structures 70-1, 70-2, . . . , 70-n (sometimes referred to herein as CCD charge storage structures or CCD storage wells). CCD structures 70-1, 70-2, . . . , 70-n may be referred collectively as a CCD register. CCD structures 70 may be coupled along a serial path having CCD structure 70-1 at an end that is coupled to a photodiode (e.g., CCD structure 70-1 may be coupled to photodiode 42 in FIG. 3).

Integration circuitry 45 may include (integration) CCD structures 74-1, 74-2, . . . , 70-n (sometimes referred to herein as CCD charge storage structures or CCD storage wells). Integration CCD structures 74-1, 74-2, . . . , 70-n may be referred to collectively as an (integration) CCD register. CCD structures 74 may be coupled along a serial path having CCD structure 74-n at an end that is coupled to a floating diffusion region (e.g., CCD structure 74-n may be coupled to floating diffusion region 48 via transistor 58 in FIG. 3).

As an example, each CCD register (e.g., one for time trace circuitry 44 and one for integration circuitry 45) may include about 450 stages (e.g., CCD structures). If desired any other number of stages may be used.

In the example of FIG. 4, every third serially-connected CCD structure 70 in time trace circuitry 44 may have a direct connection to every third serially-connected CCD structure 74 in integration circuitry 45. As an example, respective charge transfer structures 72 may couple every third serially-connected CCD structure 70 to every third serially-connected CCD structure 74. Charge transfer structures 72 may be implemented using (e.g., may be or may include) transistor structures, CCD structures, MOS capacitor structures, and/or or any other structure configured to selectively transfer charge based on one or more control signals. Charge transfer structures 72 may be referenced as being separate from integration circuitry 45 or as being a part of integration circuitry 45.

In the configuration of CCD structures 70 having interconnections with integration circuitry 45 in sets of three, different CCD structures 70 in each set of three may receive three different control signals C1, C2, and C3. Each of control signals C1, C2, C3 may correspond to a different voltage level. By using control signals C1, C2, and C3, charge may be transferred from one CCD structure 70 to another (adjacent) CCD structure 70 in a serial and sequential manner. In the configuration of CCD structures 74 having interconnections with integration circuitry 44 in sets of three, different CCD structures 74 in each set of three may receive three different control signals C5, C6, and C7. Each of control signals C5, C6, C7 may correspond to a different voltage level. By using control signals C5, C6, C7, charge may be transferred from one CCD structure 74 to another (adjacent) CCD structure 74 in a serial and sequential manner. Charge transfer structures 72 may receive control signal C4, which control when charge is transferred from a given CCD structure 70 to a corresponding CCD structure 74 through a corresponding charge transfer structure 72.

In some applications, control circuitry (e.g., row control circuitry 26 and/or control circuitry 24 in FIG. 2) may provide control signals C1-C7 to accumulate or integrate multiple sets of charges at integration circuitry 45 before reading out the integrated charge from integration circuitry 45 (e.g., through floating diffusion region 48 in FIG. 3, through pixel output line 32 in FIG. 3, to readout circuitry 28 in FIG. 2, etc.). As an example, time trace generation circuitry 44 (e.g., CCD structures 70) may be operated (e.g., clocked) at a higher speed (using control signals C1-C3) than the speed at which integration circuitry 45 (e.g., CCD structures 74) is operated (using control signals C5-C7). In particular, time trace generation circuitry 44 may be operated at speeds of about 250 MHz or any other suitable speeds such as speeds greater than 100 MHz, speeds greater than 250 MHz, etc.

The difference in operating speeds allows multiple sets of charge for multiple time traces (e.g., two sets of charge for two time traces, three sets of charge for three time traces, five sets of charge for five time traces, etc.) to be transferred across the serially-connected CCD structures 70, with each set of charge being transferred to CCD structure 74 and accumulated or integrated with the other sets of charge. Thereafter, the accumulated charge for an integrated time trace stored at CCD structures 74 may be transferred across the serially-connected CCD structures 74 and read out in a serial and sequential manner as an output of integration circuitry 45 (e.g., to a floating diffusion region in the example of FIG. 4).

By implementing integration circuitry 45 along with time trace circuitry 44, signal-to-noise ratio for the gathered time trace information (e.g., integrated charge corresponding to the integrated time trace) may be improved when compared to that of a single set of charge for a single time trace. Additionally, this may enable readout circuitry and other circuitry downstream from time trace circuitry 44 to operate at reduced speeds (e.g., at lower frequencies).

The configuration in FIG. 4 is merely illustrative. If desired, any CCD structure 70 for time trace circuitry 44 may have a direct connection to a corresponding CCD structure 74 for integration circuitry 45. As examples, every CCD structure 70 in time trace circuitry 44 may have a direct connection to a corresponding CCD structure 74 in integration circuitry 45 (e.g., through a corresponding charge transfer transistor 72), every two CCD structures 70 in time trace circuitry may have a direct connection to a corresponding CCD structure 74 in integration circuitry 45, every four CCD structure 70 in time trace circuitry 44 may have a direct connection to a corresponding CCD structure 74 in integration circuitry 45, etc. If desired, CCD structures 70 may be organized in sets of more or less than three and/or may receive more or less than three control signals (or voltages). If desired, CCD structure 74 may be organized in sets of more or less than three and/or may receive more or less than three control signals (or voltages).

In other words, the illustrative configuration shown in FIG. 4 is for a three-phase CCD. If desired, CCDs of other phases, such as uni-phase CCDs, two-phase CCDs, four-phase CCDs, etc., may be used (instead of the three-phase CCD configuration in FIG. 4). Additionally, if desired, charge transfer structures 72 may be combined into a single structure with corresponding CCD structures 74 to form integral CCD structures or gates.

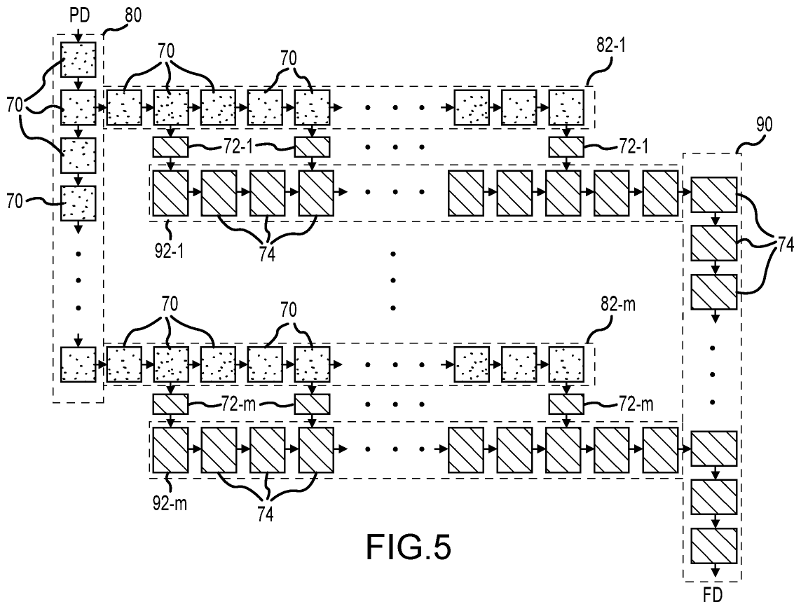

In some configurations, time trace circuitry and integration circuitry may each include more than one serial paths (e.g., may include branches off of a serial path). FIG. 5 is a diagram showing illustrative time trace generation circuitry and illustrative integration circuitry each having multiple branches or serial paths. Control signal connections to CCD structures are omitted from FIG. 5 in order to not unnecessarily obscure the present embodiments.

As shown in FIG. 5, time trace circuitry may include a first serial path 80 (sometimes referred to herein as portion 80), and one or more other serial paths 82-1, 82-2 (not explicitly shown in FIG. 5), . . . , 82-n (sometimes referred to herein as portions 82-1, 82-2, . . . , 82-n). Integration circuitry may include a first serial path 90 (sometimes referred to herein as portion 90), and one or more other serial paths 92-1, 92-2 (not explicitly shown in FIG. 5), . . . , 92-n (sometimes referred to herein as portions 92-1, 92-2, . . . , 92-n.

By separating time trace circuitry into multiple serial paths (e.g., path 80 with branching serials paths 82), different portions of time trace circuitry may operate at different speeds. In particular, serial path 80 may operate (e.g., based on control signals) at a speed (e.g., an operating frequency) that is greater than a speed at which serial paths 82 may be operated. Integration circuitry may still operate at a speed less than any portion of time trace circuitry. If desired, different portions of integration circuitry may similarly operate at different speeds (e.g., portion 90 may operate at a speed that is greater than a speed at which serial paths 92 may be operated).

A photodiode may similarly be coupled to a CCD structure 70 at an end of portion 80. As an example, serial paths 82 may be coupled to every third CCD structure 70 in serial path 80. As another example, each branching serial path 82 may have CCD structures 70, every third of which is directly connected to a corresponding CCD structure in a corresponding branching serial path 92 via a corresponding charge transfer structure 72. Similarly, serial paths 92 may be coupled to every third CCD structure 74 in serial path 90. A floating diffusion region may be coupled to a CCD structure at an end of portion 90.

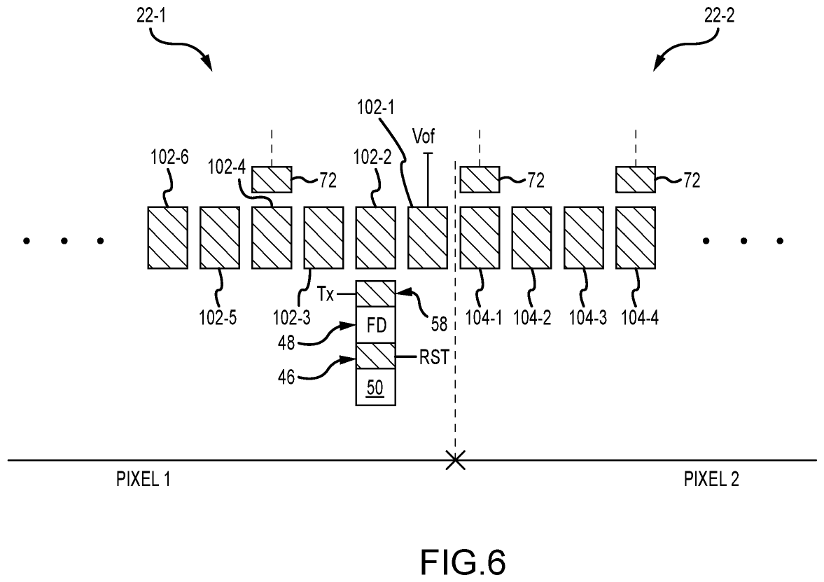

FIG. 6 is a diagram of illustrative integration circuitry (sometimes referred to herein as time trace integration circuitry) having background light subtraction capabilities. As shown in FIG. 6, a first pixel 22-1 may have integration circuitry comprising charge storage structures 102-1, 102-2, 102-3, 102-4, 102-5, 102-6, etc. (e.g., CCD structures, corresponding to CCD structures 74 in FIGS. 4 and 5 for a first pixel). A second pixel 22-2 may have integration circuitry comprising charge storage structure 104-1, 104-2, 104-3, 104-4, etc. (e.g., CCD structures, corresponding to CCD structures 74 in FIGS. 4 and 5 for a second pixel). If desired, charge storage structure 102-1 may be an overflow transistor or gate, or any other structure suitable to set a voltage barrier.

Charge storage structure 102-1 in pixel 22-1 may be connected to CCD structure 104-1 in pixel 22-2 (in addition to being coupled to other CCD structures 102 in the integration circuitry in pixel 22-1). Charge storage structure 102-1 (sometimes referred to herein as a charge barrier structure) may receive a barrier voltage Vof (e.g., at a terminal of charge storage structure 102-1) which provide a voltage barrier for charge transferred between charge storage structures 102-2 and 104-1.

As an example, charge storage structure 102-2 may store an integrated charge. When charge storage structure 102-2 transfers the integrated charge to CCD structure 104-1 (through voltage barrier structure 102-1), only the portion of the integrated charge above the voltage barrier set by structure 102-1 may be transferred to CCD structure 104-1 and the remaining portion of the integrated charge below the voltage barrier may remain at charge storage structure 102-2 (because of the voltage or charge barrier set by structure 102). The remaining portion of the charge may be removed from charge storage structure 102-2 via a reset path. In the example of FIG. 6, the reset path may be a path coupling CCD structure 102-2 to supply terminal 50 via transistor 58, floating diffusion region 48, and reset transistor 46. In other words, the remaining charge may be transferred to supply terminal 50 and removed. This is merely illustrative. If desired, other reset paths or methods may be used to remove the remaining charge at charge storage structure 102-2. As an example, a transistor may directly connect structure 102-2 to supply terminal 50 to form the reset path.

In some configurations, a background light level may be measured with image sensor 16 (FIGS. 1 and 2) without emitting light from a light source to gather time-of-flight information. The measured background light level may be used to determine the voltage level of voltage Vof. If desired, control circuitry may set an external control loop to actively control and vary voltage Vof (according to the background light level).

Without integrating any new charge from time trace generation circuitry (not shown in FIG. 6), charge stored at each of charge storage structures 102-2, 102-3, 102-4, etc., in pixel 22-1 may be moved to charge storage structures 104 (e.g., structures 104-1, 104-2, etc.) in pixel 22-2 by moving charge across the voltage barrier set by structure 102-1. After each step movement, the remaining charge at structure 102-2 may be removed via the reset path. This may ensure that only the proper amount of overflow charge is transferred to charge storage structures 104 in pixel 22-2 for each of the charge initially stored at charge storage structures 102-2, 102-3, 102-4, etc. After all of the corresponding charge stored at charge structure structures 102 have crossed the (overflow) voltage barrier, the voltage barrier at structure 102-1 may be removed and the moved charge may be moved back to charge storage structures 102 in pixel 22-1 from charge storage structures 104 in pixel 22-2.

In other words, after an illustrative example with four step-wise movements charge, the overflow charge portion from structure 102-2 may be temporarily stored at structure 104-4, the overflow charge portion from structure 102-3 may be temporarily stored at structure 104-3, the overflow charge portion from structure 102-4 may be temporarily stored at structure 104-2, and the overflow charge portion from structure 102-5 may be temporarily stored at structure 104-1. After a suitable number of step-wise movements of charge, these respective overflow charge portions may be returned to their initial corresponding charge storage structures 102-2, 102-3, 102-4, etc. in pixel 22-1 (after being temporarily stored at charge storage structures 104 in pixel 22-2).

The overflow voltage barrier at structure 102-1 may serve as (e.g., may be referred to as) background light subtraction circuitry that subtract the background light voltage (or charge associated with the background light) from the integrated charge stored in integration circuitry of pixel 22-1. This process uses charge storage structure 104 in pixel 22-2 as temporary storage for the resulting charge before moving the resulting charge back into the integration circuitry of pixel 22-1. This may further save space by utilizing circuitry of adjacent pixels. Similarly, pixel 22-2 may include its own overflow voltage barrier and reset path, and may analogously use pixel 22-3 (not shown) to temporarily store any resulting charge. If desired, an excess (inactive) pixel may be used to temporarily hold the resulting charge for the last active pixel. By performing background light level subtraction, pixel circuitry further increases the signal-to-noise ratio of the integrated charge (e.g., integrated time trace information) without saturating the integration CCD structures.

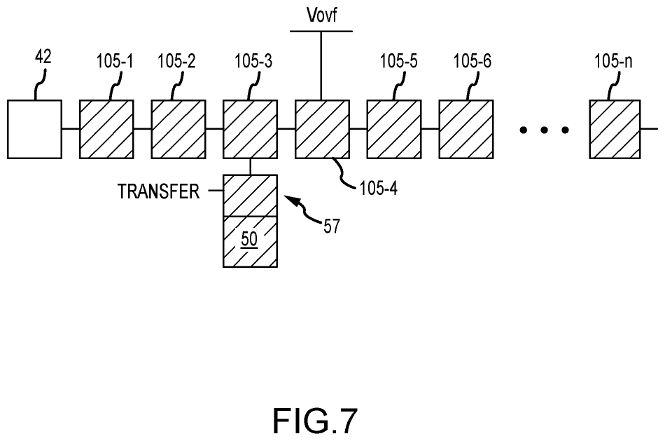

FIG. 7 is a diagram of an illustrative configuration for implementing background light subtraction capabilities at the time trace generation circuitry (e.g., time trace circuitry 44 in FIG. 3). As shown in FIG. 7, photodiode 42 may be coupled to a set of charge storage structures 105-1, 105-2, . . . , 105-n (similar to the configurations in FIGS. 4 and 5).

A given one of these charge storage structures (e.g., charge storage structure 105-4 sometimes referred to herein as a charge barrier structure) may receive a barrier voltage Vovf (e.g., at a terminal of charge storage structure 105-4). This may provide a voltage or charge barrier for charge transferred between charge storage structures 105-3 and 105-5. In particular, when charge is transferred across the voltage barrier (e.g., across charge storage structure 105-4) from charge storage structure 105-3 to charge storage structure 105-5, only the overflow portion of the charge above the voltage level set by the voltage barrier may be transferred to structure 105-5. The portion of the charge below the voltage level may remain at charge storage structure 105-3. This remaining portion of charge maybe removed via a reset path coupling charge storage structure 105-3 to supply terminal 50. The reset path may include a charge transfer structure (e.g., a transistor) controlled by control signal TRANSFER that directly connects structure 105-3 to supply terminal 50 (without an intervening floating diffusion region). This is merely illustrative. If desired, the reset path may include other charge transfer structures or components.

As an example, a charge or voltage barrier structure such as structure 105-4 (and one or more additional charge storage structures 105-3, 105-2, etc.) may be disposed between a photodiode PD and charge storage structure 70-1 in FIG. 4. If desired, a charge barrier structure may be placed elsewhere within pixel 22. Barrier voltage Vovf may similarly be varied according to a background light level as described in connection with FIG. 6. Hence, the pixel configuration in FIG. 7 may also perform background light subtraction, which also increases the signal-to-noise ratio of the integrated charge.

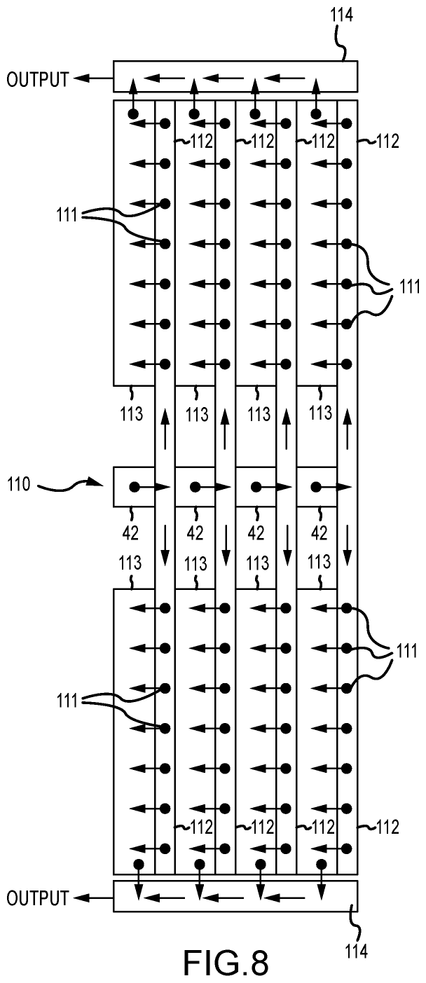

FIG. 8 is a diagram of an illustrative configuration for coupling an array of photosensitive elements, which are sometimes referred to herein as an array of photosensitive regions, to integrated time trace generation circuitry (referring to a combination of time trace circuitry and integration circuitry). The array of photosensitive elements may be provided within a single pixel (e.g., pixel 22 in FIG. 2) or may be associated with an array of pixels (e.g., array 20 in FIG. 2). As shown in FIG. 8, a photosensitive region array 110 may include photosensitive regions 42. Each photosensitive region may be coupled to a column (column 112) of charge storage regions 111 (e.g., CCD structures). The column of charge storage regions 111 may include two channels, one of which leads to an upper column set of charge storage regions 111 and the other one of which leads to a lower column set of charge storage regions 111.

In the example of FIG. 8, charge generated at each photosensitive region 42 may be transferred to either an upper column set of charge storage regions 111 or a lower column set of charge storage regions 111. Each of the upper and lower column set of charge storage regions 111 may be coupled a single charge integration region 113 for integrating the charge in the corresponding set of charge storage regions 111. The upper set of charge integration regions 113 may be coupled to an output set of charge storage structures (e.g., upper CCD structures 114). The lower set of charge integration regions 113 may be coupled to an additional output set of charge storage structures (e.g., lower CCD structures 114). CCD structures 114 may each have an output that may be coupled to readout circuitry, a floating diffusion region, a pixel output line, etc.

The configuration in FIG. 8 is merely illustrative. If desired, array 110 of photosensitive regions 42 may include any suitable number of photosensitive regions. If desired, multiple sets of array 110 may be replicated across pixel array 20 in FIG. 2. If desired, each photosensitive region 42 may be coupled to only one of an upper column set of structures 111 or a lower column set of structures 111. If desired, the output of each charge integration region 113 may be read out separately (e.g., without CCD structures 114).

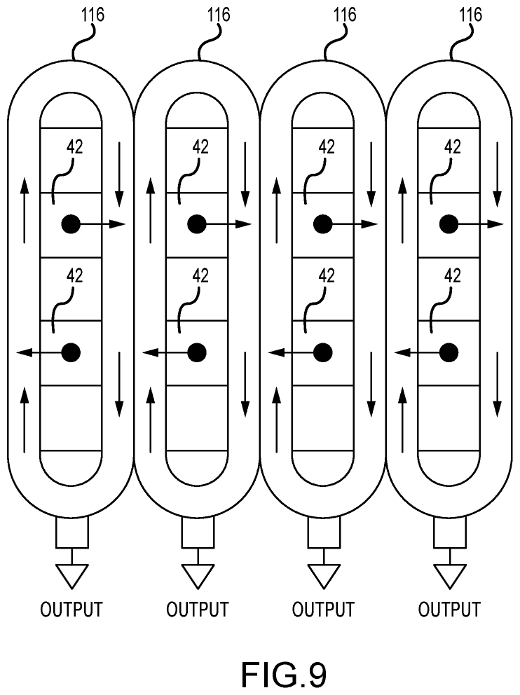

FIG. 9 is a diagram of illustrative time trace generation circuitry configured in a loop in accordance with some embodiments. As shown in FIG. 9, an array of photosensitive regions may be organized as pairs of photosensitive regions 42. Each pair of photosensitive region 42 may be surrounded by a loop of charge storage structures 116 (e.g., CCD structures). Each loop of charge storage structures 116 may include straight portions and curved portions. Each pair of photosensitive regions 42 may both transfer charge onto a corresponding loop of charge storage structures 116 at two different locations. As such, charge generated from that pair of photosensitive regions 42 may be read out from the same loop of charge storage structures 116. This may allow the pixel pair (or two pixel rows, when the array is collectively operated) to be simultaneously read out using a corresponding loop 116 of suitable length.

Additionally, if desired, the charge storage structures 116 may both generate and integrate charge received from photodiode 42. As an illustrative configuration, each loop of charge storage structures 116 may be coupled to a single photodiode 42 (e.g., one of each pair of the photodiodes 42 in FIG. 9 may be omitted). Different sets of charge generated by the single photodiode 42 (associated with different time traces) may be received by (e.g., sampled by) and integrated at the corresponding loop of charge storage structures 116. After integration of a suitable set of charges (associated with corresponding time traces), the integrated charge may be output by the loop of charge storage structures 116. If desired, charges from more than a single photodiode 42 (e.g., charge from two photodiodes 42) may be separated integrated at a single loop of charge storage structure 116.

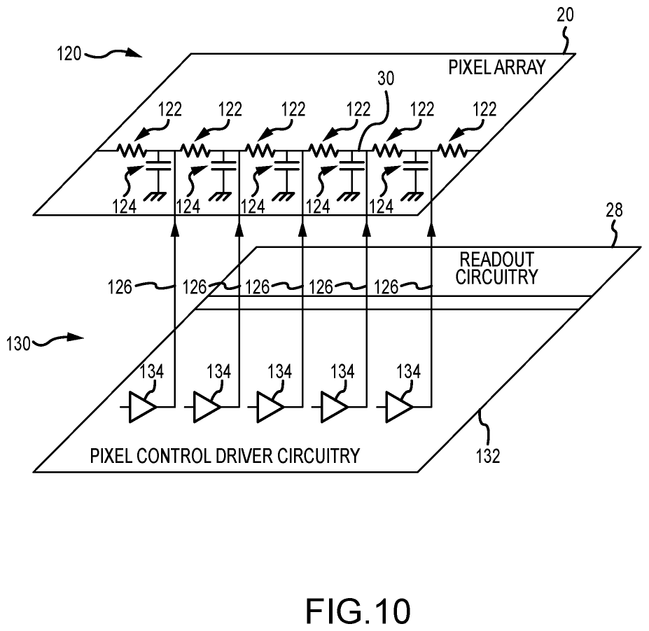

FIG. 10 is a diagram of control driver circuitry and pixel circuitry implemented on separate stacked dies. As shown in FIG. 10, pixel circuitry such as pixel array 20 may be formed on a first die 120. Pixel array 20 may include or more (pixel) control lines 30. A given control line 30 may have resistive elements 122 and capacitive elements 124. Drive circuitry such as pixel control driver circuitry 132 have drivers 134 coupled to different portions of column line 30 via paths 126. Paths 126 may be formed from vias, interlayer connections, interconnect layers, bumps, solder, hybrid bonding structures, etc.

In the example of FIG. 10, pixel control driver circuitry 132 may be formed on a second die (along with readout circuitry 28). By stacking the first die having the pixel array 20 with the second die having pixel control driver circuitry 132, proper clock distribution and distributed pixel control circuitry 132 with synchronous operation can be more easily achieved especially for a large sensor system.

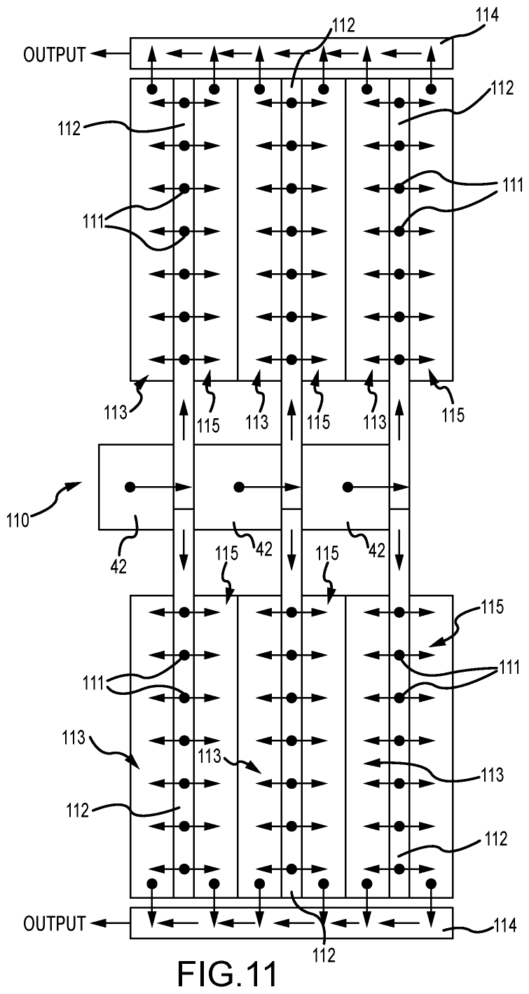

While the illustrative configuration of FIG. 8 shows each column (column 112) of charge storage regions 111 being coupled to a corresponding charge integration region 113 (sometimes referred to herein as pulse accumulator circuitry or register 113), each column 112 of charge storage regions 111 may also be coupled to background (light) accumulation circuitry or register 115 (sometimes referred to as background integration region 115). This illustrative configuration is shown in FIG. 11.

In particular, a given upper or lower column portion of charge storage regions 111 may be coupled to charge integration region 113 on one side to selectively accumulate one or more time traces (e.g., image signals from pulsed light) and may be coupled to background integration region 115 on the other side to selectively accumulate one or more background light signal. Both the accumulated time traces and the background light signal may be read out using charge storage structure 114. Processing and control circuitry, charge storage structures 114, and/or other circuitry may be configured to subtract the background light (signal) from the accumulated time traces to further improve SNR.

Various embodiments have been described illustrating systems and methods generating time trace information and gathering time of flight measurements.

As an example, an image sensor may include a photosensitive element, time trace generation circuitry having a first charge-coupled device register and coupled to the photosensitive element, time trace integration circuitry having a second charge-coupled device register, coupled to the first charge-coupled device register via a plurality of charge transfer structures, and configured to generate integrated time trace information, and readout circuitry coupled to the time trace integration circuitry and configured to perform readout operations on the generated integrated time trace information. The time trace generation circuitry may include a first plurality of charge-coupled device structures coupled along a first serial path that form the first charge-coupled device register. The time trace integration circuitry may include a second plurality of charge-coupled device structures coupled along a second serial path that form the second charge-coupled device register.

If desired, only a subset of the first plurality of charge-coupled device structures may have a direct connection to a corresponding subset of the second plurality of charge-coupled device structures via the plurality of charge transfer structures. If desired, each charge-coupled device structure in the first plurality of charge-coupled device structures may have a storage capacity that is less than a storage capacity of each charge-coupled device structure in the second plurality of charge-coupled device structures. If desired, the time trace generation circuitry may be operable at a first operating frequency, and the time trace integration circuitry may be operable at a second operating frequency that is less than the first operating frequency.

If desired, the time trace generation circuitry may include a third plurality of charge-coupled device structures coupled along a third serial path. The first serial path may have an end coupled to the third serial path, and the third serial path may be coupled to the second serial path via the first serial path. If desired, the third plurality of charge-coupled device structures may be operable at a first speed, and the first plurality of charge-coupled device structures are operable at a second speed that is less than the first speed. If desired, the second plurality of charge-coupled device structures may be operable at a third speed that is less than the second speed.

If desired, the time trace integration circuitry may include a fourth plurality of charge-coupled device structures coupled along a fourth serial path. The second serial path may have an end coupled to the fourth serial path, and the fourth serial path may be coupled to the first serial path via the second serial path. If desired, the third serial path may have an end coupled to the photosensitive element and the fourth serial path may have an end coupled to an output path connected to the readout circuitry.

If desired, the second serial path may be coupled to a voltage barrier structure configured to receive a barrier voltage level and configured to transfer a first portion of charge that is above the barrier voltage level and store a second portion of charge that is below the barrier voltage level. If desired, the voltage barrier structures may be coupled to a reset path coupling the voltage barrier structures to a supply terminal. The reset path may be configured to remove the second portion of charge from the voltage barrier structure.

As another example, an imaging system may include an array of photosensitive elements, a plurality of serial paths connected to the array of photosensitive elements, each serial path comprising a set of series-connected charge storage structures, and a plurality of charge accumulation circuits, each charge accumulation circuit configured to receive and accumulate charge from a corresponding set of series-connected charge storage structures in the plurality of serial paths. The imaging system may further include additional series-connected charge storage structures configured to receive accumulated charge from each charge accumulation circuit in the plurality of charge accumulation circuits and configured to output the accumulated charge at an output at one end of the additional series connected charge storage structures.

If desired, the sets of series-connected charge storage structures in the plurality of serial paths may include a charge-coupled device, and the plurality of charge accumulation circuits may include a charge-coupled device. If desired, a photosensitive element in the array of photosensitive elements may be coupled to at least two serial paths in the plurality of serial paths, a first serial path coupled to a first charge accumulation circuit in the plurality of charge accumulation circuit, a second serial path coupled to a second charge accumulation circuit in the plurality of charge accumulation circuits. If desired, charge accumulated at the first charge accumulation circuit may be provided to a first output terminal, and charge accumulated at the second charge accumulation circuit may be provided to a second output terminal.

As yet another example, an image pixel may include a photosensitive element, time trace generation circuitry coupled to the photosensitive element, charge accumulation circuitry coupled to the time trace generation circuitry and configured to accumulate charge received from the time trace generation circuitry, and subtraction circuitry coupled to the charge accumulation circuitry and configured to subtract a background light level from the accumulated charge. The time trace generation circuitry and the charge accumulation circuitry may each comprise a charge-coupled device, and the charge accumulation circuitry may be configured to accumulate the charge in the analog domain.

The foregoing is merely illustrative of the principles of this invention and various modifications can be made by those skilled in the art without departing from the scope and spirit of the invention. The foregoing embodiments may be implemented individually or in any combination.

What is claimed is:

1. An image sensor comprising:
a photosensitive element;
time trace generation circuitry having a first charge-coupled device register and coupled to the photosensitive element;
time trace integration circuitry having a second charge-coupled device register, coupled to the first charge-coupled device register via a plurality of charge transfer structures, and configured to generate integrated time trace information; and
readout circuitry coupled to the time trace integration circuitry and configured to perform a readout operation on the generated integrated time trace information.

2. The image sensor defined in claim 1, wherein the time trace generation circuitry comprises a first plurality of charge-coupled device structures coupled along a first serial path that form the first charge-coupled device register.

3. The image sensor defined in claim 2, wherein the time trace integration circuitry comprises a second plurality of charge-coupled device structures coupled along a second serial path that form the second charge-coupled device register.

4. The image sensor defined in claim 3, wherein only a subset of the first plurality of charge-coupled device structures have a direct connection to a corresponding subset of the second plurality of charge-coupled device structures via the plurality of charge transfer structures.

5. The image sensor defined in claim 3, wherein the time trace generation circuitry is operable at a first operating frequency and the time trace integration circuitry is operable at a second operating frequency that is less than the first operating frequency.

6. The image sensor defined in claim 3, wherein the time trace generation circuitry comprises a third plurality of charge-coupled device structures coupled along a third serial path, wherein the first serial path has an end coupled to the third serial path and the third serial path is coupled to the second serial path via the first serial path.

7. The image sensor defined in claim 6, wherein the third plurality of charge-coupled device structures are operable at a first speed, the first plurality of charge-coupled device structures are operable at a second speed that is less than the first speed, and wherein the second plurality of charge-coupled device structures are operable at a third speed that is less than the second speed.

8. The image sensor defined in claim 6, wherein the time trace integration circuitry comprises a fourth plurality of charge-coupled device structures coupled along a fourth serial path, and wherein the second serial path has an end coupled to the fourth serial path and the fourth serial path is coupled to the first serial path via the second serial path.

9. The image sensor defined in claim 8, wherein the third serial path has an end coupled to the photosensitive element and the fourth serial path has an end coupled to an output path connected to the readout circuitry.

10. The image sensor defined in claim 3, wherein a given charge-coupled device structure along the second serial path is coupled to a voltage barrier structure configured to receive a barrier voltage level and configured to transfer a first portion of charge that is above the barrier voltage level and store a second portion of charge that is below the barrier voltage level at the given charge-coupled device structure.

11. The image sensor defined in claim 10, wherein the given charge-coupled device structure in the second serial path is coupled to a reset path, wherein the reset path couples the given charge-coupled device structure to a supply terminal.

12. An imaging system comprising:
an array of photosensitive elements;
a plurality of serial paths connected to the array of photosensitive elements, each serial path comprising a set of series-connected charge storage structures; and
a plurality of charge accumulation circuits, each charge accumulation circuit configured to receive and accumulate charge from a corresponding set of series-connected charge storage structures in the plurality of serial paths.

13. The imaging system defined in claim 12, further comprising:
additional series-connected charge storage structures configured to receive accumulated charge from each charge accumulation circuit in the plurality of charge accumulation circuits and configured to output the accumulated charge at an output at one end of the additional series connected charge storage structures.

14. The imaging system defined in claim 12, wherein the sets of series-connected charge storage structures in the plurality of serial paths comprise a charge-coupled device and the plurality of charge accumulation circuits comprise a charge-coupled device.

15. The imaging system defined in claim 12, wherein a photosensitive element in the array of photosensitive elements is coupled to at least two serial paths in the plurality of serial paths, a first serial path coupled to a first charge accumulation circuit in the plurality of charge accumulation circuit, a second serial path coupled to a second charge accumulation circuit in the plurality of charge accumulation circuits.

16. The imaging system defined in claim 15, wherein charge accumulated at the first charge accumulation circuit is provided to a first output terminal and charge accumulated at the second charge accumulation circuit is provided to a second output terminal.

17. The imaging system defined in claim 12, further comprising:
a plurality of background light integration circuits, each background light integration circuit coupled to a corresponding set of series-connected charge storage structures in the plurality of serial paths and configured to integrate a background light signal.

18. An image pixel comprising:
a photosensitive element;
a plurality of charge-coupled device structures forming time trace generation circuitry and time trace integration circuitry, wherein a first charge-coupled device structure in the plurality of charge-coupled device structures is coupled to the photosensitive element; and
background light subtraction circuitry that includes a voltage barrier structure directly connected to a second charge-coupled device structure in the plurality of charge-coupled device structures.

19. The image pixel defined in claim 18, wherein a first portion of the plurality of charge-coupled device structures forms the time trace generation circuitry and a second portion of the plurality of charge-coupled device structures forms the time trace integration circuitry.

20. The image pixel defined in claim 19, wherein the first portion of the plurality of charge-coupled device structures includes the second charge-coupled device structure directly connected to the voltage barrier structure.

21. The image pixel defined in claim 19, wherein the second portion of the plurality of charge-coupled device structures includes the second charge-coupled device structure directly connected to the voltage barrier structure.
